(19) United States
(12) Patent Application Publication
(10) Pub. No.: US 2025/0089337 A1
(43) Pub. Date: Mar. 13, 2025

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Viraj Nilesh MADHIWALA, Kessel-Lo (BE); Georgios VELLIANITIS, Heverlee (BE); Marcus Johannes Henricus VAN DAL, Linden (BE); Oreste MADIA, Bruxelles (BE)

(73) Assignee: TAIWAN SEMICONDUCTOR MANUFACTURING COMPANY, LTD., Hsinchu (TW)

(21) Appl. No.: 18/466,565

(22) Filed: Sep. 13, 2023

(51) Int. Cl. H01L 29/417; H01L 29/06; H01L 29/40; H01L 29/423; H01L 29/66; H01L 29/775; H01L 29/786

(52) U.S. Cl. CPC H10D 64/258; H10D 30/43; H10D 30/6735; H10D 30/6757; H10D 62/121; H10D 64/01; H10D 64/018

(57) ABSTRACT

A semiconductor device includes a substrate. Semiconductor channel layers are over the substrate. A gate structure wraps around each of the semiconductor channel layers. Source/drain epitaxial structures are on opposite sides of the gate structure. An inner spacer is vertically between adjacent two of the semiconductor channel layers. A dielectric protective layer is on a sidewall of the inner spacer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 13 illustrate a method in various stages of forming a semiconductor device in accordance with some embodiments of the present disclosure.

FIGS. 14A to 14D illustrate an exemplary process of selective deposition process of protective layer in some embodiments of the present disclosure.

FIG. 15 illustrates a semiconductor device in accordance with some embodiments of the present disclosure.

FIGS. 16A to 16C illustrate a method in various stages of forming a semiconductor device in accordance with some embodiments of the present disclosure.

FIGS. 17A to 17C illustrate a method in various stages of forming a semiconductor device in accordance with some embodiments of the present disclosure.

FIGS. 18A to 18B illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure. Although embodiments of the present disclosure is explained with respect to a GAA structure, embodiments of the disclosure may also be applied, however, to a variety of metal oxide semiconductor transistors (e.g., complementary-field effect transistor (CFET)).

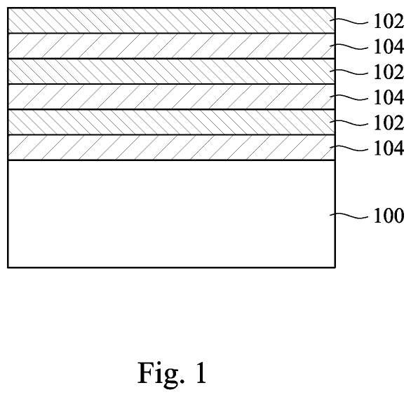

FIGS. 1 to 13 illustrate a method in various stages of forming a semiconductor device in accordance with some embodiments of the present disclosure. Although FIGS. 1 to 13 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 1. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A semiconductor stack is formed over the substrate 100. The semiconductor stack includes alternating semiconductor layers 102 and 104. In some embodiments, the semiconductor layers 102 may be made of pure silicon layers that are free of germanium. The semiconductor layers 102 may also be substantially pure silicon layers, for example, with a germanium percentage lower than about 1 percent. The semiconductor layers 104 may be made of silicon germanium. For example, the germanium percentage (atomic percentage concentration) of the semiconductor layers 104 is in a range from about 20 percent and about 40 percent. In some embodiments, the semiconductor layers 102 and 104 may be deposited using suitable deposition process, such as selective epitaxial growth (SEG), chemical vapor deposition (CVD), molecular beam epitaxy (MBE), or other suitable process(es). In some embodiments, the semiconductor layers 104 may be removed during a replacement gate (RPG) process, and thus the semiconductor layers 104 can also be referred to as sacrificial layers. In some embodiments, the semiconductor layers 102 may serve as channel regions of a transistor, and thus the semiconductor layers 102 can also be referred to as semiconductor channel layers. In some embodiments, the semiconductor stack is patterned to form a fin-like structure that protrudes from a top surface of the substrate 100, and thus the semiconductor stack may also be referred to as a fin structure.

In some embodiments, the semiconductor layers 102 can be interchangeably referred to as nanosheets, nanowires, nanoslabs, nanorings, or nanostructures having nano-scale size (e.g., a few nanometers), depending on their geometry. It is understood that the number of the semiconductor layers 102 is merely used to explain, and the present disclosure is not limited thereto. In other embodiments, more or less semiconductor layers 102 may also be applied.

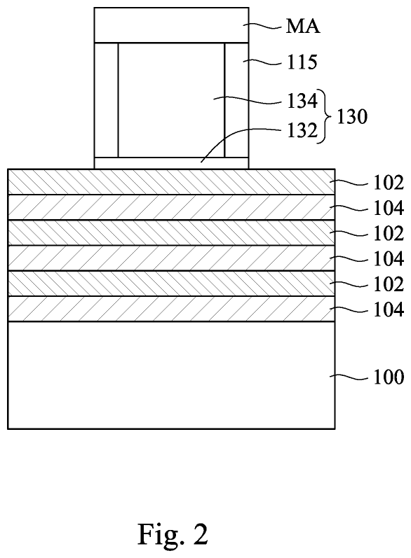

Reference is made to FIG. 2. A dummy gate structure 130 is formed over the substrate 100 and crossing the semiconductor stack. In some embodiments, the dummy gate structure 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals.

Gate spacers 115 are formed on opposite sidewalls of the dummy gate structure 130. In some embodiments, the gate spacers 115 may be formed of silicon oxide, silicon nitride, silicon oxynitride, combinations thereof. In some embodiments, the gate spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structure 130. In some embodiments, the remaining vertical portions of the spacer layer on sidewalls of the dummy gate structures 130 can be referred to as gate spacers 115. In some embodiments, the spacer layer may be deposited using techniques such CVD, ALD, or the like. In some embodiments, the dummy gate dielectric 132 extends to regions vertically below the gate spacers 115.

A hard mask MA is formed over the dummy gate structure 130. In some embodiments, the hard mask MA includes silicon nitride, silicon oxide, combinations thereof, or the like. In some embodiments, the hard mask MA covers top surfaces of the gate spacers 115.

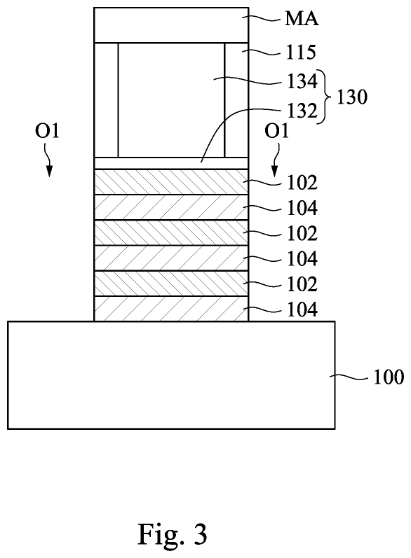

Reference is made to FIG. 3. An etching process is performed to remove portions of the semiconductor stack by using the hard mask HM (or dummy gate structure 130 and the gate spacers 115) as etch mask, so as to form source/drain openings O1 in the semiconductor stack. In some embodiments, the etching process may be wet etch, dry etch, or combinations thereof. In some embodiments, bottommost ends of the source/drain openings O1 may be lower than top surface of the substrate 100.

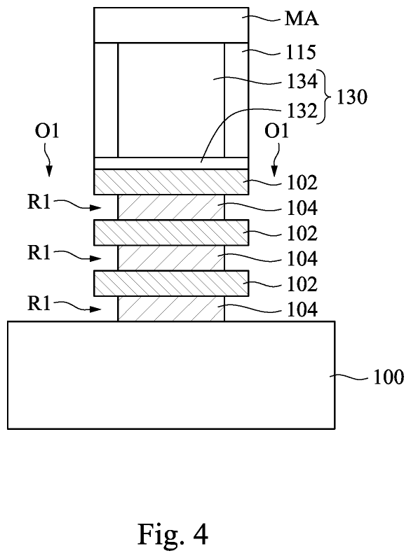

Reference is made to FIG. 4. After the source/drain openings O1 are formed, the semiconductor layers 104 are laterally etched to form sidewall recesses R1. In some embodiments, the sidewalls of the semiconductor layers 104 may be etched using isotropic etching processes, such as wet etching or the like. In some embodiments where the semiconductor layers 104 include, e.g., SiGe, and the semiconductor layers 102 include, e.g., Si, an etch process with tetramethylammonium hydroxide (TMAH), ammonium hydroxide (NH₄OH), or the like may be used to etch sidewalls of the semiconductor layers 104.

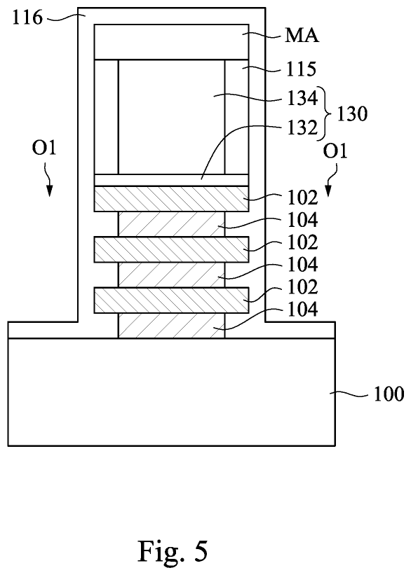

Reference is made to FIG. 5. An inner spacer layer 116 is deposited blanket over the structure illustrated in FIG. 4. In some embodiments, the inner spacer layer 116 may fill the sidewall recesses R1 on opposite ends of the semiconductor layers 104. The inner spacer layer 116 may be deposited by a conformal deposition process, such as CVD, ALD, or the like. The inner spacer layer 116 may comprise a material such as silicon oxide (SiO₂), silicon nitride (SiN), silicon oxycarbide (SiOC), or silicon oxynitride (SiON), although any suitable material, such as low-k materials having a k-value less than about 3.5, may be utilized.

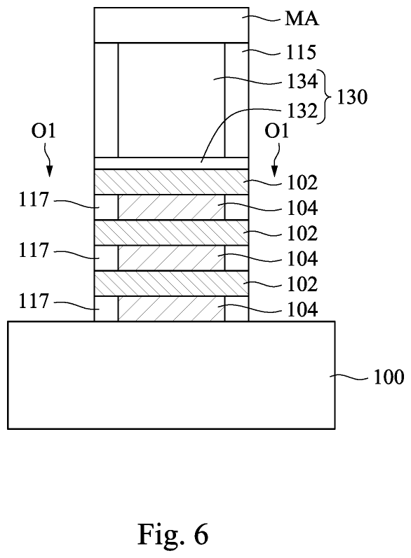

Reference is made to FIG. 6. An etching process is performed to remove portions of the inner spacer layer 116, while leaving portions of the inner spacer layer 116 in the sidewall recesses R1 remain as inner spacers 117. In some embodiments, the semiconductor layers 102 are exposed after the etching process. The inner spacer layer 116 may be etched through an anisotropic etching process, such as RIE, NBE, or the like. Although the inner spacers 117 are illustrated as having linear sidewall profiles, the sidewalls of the inner spacers 117 may also be convex, concave, or the like.

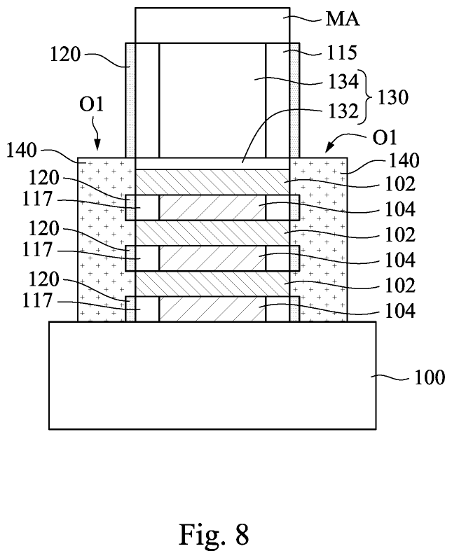

After the inner spacers 117 are formed, a pre-clean process is performed before the epitaxial growth process (e.g., the epitaxial growth process of FIG. 8), so as to remove native oxide on exposed surfaces of the semiconductor layers 102 and the substrate 100. For example, a wet clean using dilute ammonium hydroxide solution and/or SiCoNi clean process may be utilized.

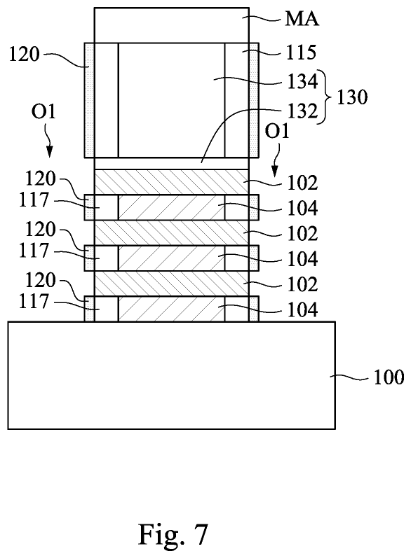

Reference is made to FIG. 7. Protective layers 120 are formed on exposed surfaces of the inner spacers 117 and/or the gate spacers 115. The bottommost protective layers 120 that are in contact with the bottommost inner spacers 117 may also be in contact with the substrate 100. In some embodiments, the protective layers 120 may be made of dielectric material, and can also be referred to as dielectric layers. For example, the protective layers 120 may be made of silicon nitride (SiN), boron nitride (BN), or other suitable dielectric material. In some embodiments, the protective layers 120 may be formed of a different material than the inner spacers 117. In other embodiments, the protective layers 120 may be formed of a same material as the inner spacers 117. In some embodiments, the protective layers 120 may be made of polymer material.

In some embodiments, a lateral width of each protective layer 120 is less than a lateral width of the respective inner spacer 117. For example, the each protective layer 120 may include a lateral width in a range from about 2 nm to about 5 nm, while each inner spacer 117 may include a lateral width in a range from about 1 nm to about 10 nm.

In some embodiments, the protective layers 120 may be formed using a selective deposition process, such that the protective layers 120 have higher growth rate on surfaces of the inner spacers 117 and the gate spacers 115 than on the surfaces of the semiconductor layers 102 and the substrate 100. In some embodiments, the protective layers 120 may not be formed on the exposed surfaces of the semiconductor layers 102 and the substrate 100. That is, the exposed surfaces of the semiconductor layers 102 and the substrate 100 are free of coverage by the protective layers 120.

In a first embodiment, the selective deposition of the protective layers 120 can be performed by passivating the exposed surfaces of the semiconductor layers 102 and the substrate 100. For example, the surface passivation process may include forming inhibitors on the exposed surfaces of the semiconductor layers 102 and the substrate 100. The inhibitors may suppress the deposition rate of the protective layers 120, which allows the protective layers 120 being selectively formed on the exposed surfaces of the inner spacers 117 and the gate spacers 115. After the protective layers 120 are formed, the inhibitors may be removed using suitable etching process, such as plasma etching.

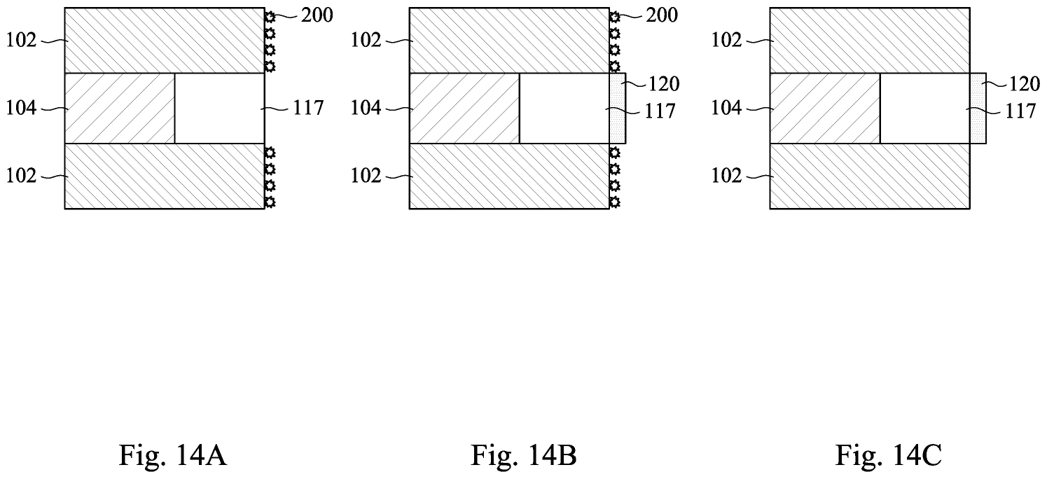

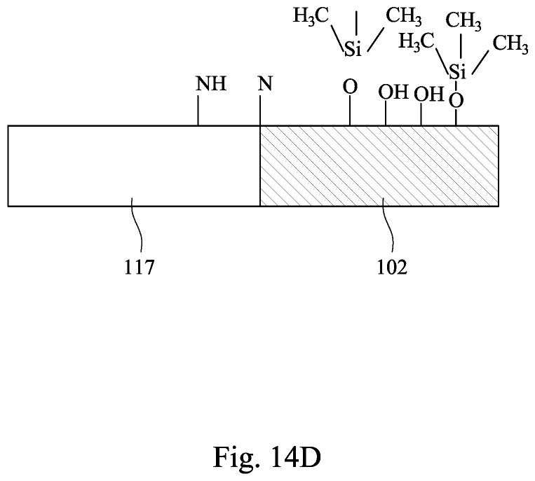

FIGS. 14A to 14D illustrate an exemplary process of selective deposition process of protective layer in some embodiments of the present disclosure. It is noted that some elements of FIGS. 14A to 14D are the same as those described with respect to FIGS. 1 to 13, such elements are labeled the same and relevant details will not be repeated for brevity.

FIGS. 14A to 14D illustrate an area-selective deposition (ASD) process. Typically, in an ASD process, a material is deposited on one surface pattern selectively to another surface pattern. The surface on which material is deposited is referred to as the growth surface, while the surface on which no deposition is desired is referred to as the non-growth surface. ASD is typically achieved by using chemical selectivity of deposition processes such as Atomic Layer Deposition (ALD) or Chemical Vapor Deposition (CVD).

In FIG. 14A, a surface passivation process is performed to passivate the semiconductor layers 102 (and/or the substrate 100, see FIG. 7). In greater detail, small molecular inhibitors (SMIs) 200 are formed on the exposed surfaces of the semiconductor layers 102 (and the substrate 100) as a result of the surface passivation process. In some embodiments, the surface passivation process may include using dimethylamino-trimethylsilane (DMA-TMS), which can passivate the surfaces of the semiconductor layers 102. For example, when the semiconductor layers 102 are made of silicon or amorphous silicon (a-Si), DMA-TMS may react with the semiconductor layers 102 to form —Si(CH₃)₃ groups (inhibitors 200) on the surfaces of the semiconductor layers 102. For example, as shown in FIG. 14D, several —Si(CH₃)₃ groups are formed on the semiconductor layers 102. On the other hand, when the inner spacers 117 (and/or the gate spacers 115, see FIG. 7) include nitride-based material, such as silicon nitride, the surfaces of the inner spacers 117 may include-NH groups, while —NH groups are less reactive with DMA-TMS. Accordingly, no —Si(CH₃)₃ group is formed on exposed surfaces of the inner spacers 117. In some embodiments, the —Si(CH₃)₃ terminated surfaces of the semiconductor layers 102 can be referred to as passivated surfaces, while the surfaces of the inner spacers 117 can be referred to as non-passivated surfaces. In some other embodiments of the present disclosure, the inhibitors 200 may also be polymer materials, such as pyromellitic dianhydride (PMDA), diaminohexane (DAH), or the like.

In FIG. 14B, after the surface passivation process is complete, a deposition process is performed to form the protective layers 120 on the non-passivated surfaces of the inner spacers 117 (and/or the gate spacers 115, see FIG. 7). In some embodiments, the inhibitors 200 (e.g., the —Si(CH₃)₃ groups) may suppress the growth rate of the protective layers 120. That is, the protective layers 120 may include higher deposition rate on the inner spacers 117 than on the inhibitors 200. As a result, the protective layers 120 may be selectively formed on the non-passivated surfaces of the inner spacers 117 (and/or the gate spacers 115, see FIG. 7). In some embodiments, the surfaces of the inhibitors 200 are free of coverage by the material of the protective layers 120.

In FIG. 14C, after the deposition process is complete, an etching process is performed to remove the inhibitors 200. As a result of the etching process, the surfaces of the semiconductor layers 102 are exposed. In some embodiments, the etching process may include plasma etching using H₂/Ar.

In some embodiments, the ASD process may include performing a plurality of deposition cycles. For example, each deposition cycle may include a surface passivation process, a deposition process, and an etching process as described in FIGS. 14A to 14C, which allows the protective layers 120 having desired thickness.

In a second embodiment, the selective deposition of the protective layers 120 can be performed by depositing boron nitride (BN). BN can be selectively deposited only on the inner spacers 117. That is, when the protective layers 120 are made of BN, the protective layers 120 can be selectively formed on the inner spacers 117 (and/or the gate spacers 115) without surface passivation treatment.

In a third embodiment, the selective deposition of the protective layers 120 can be performed by passivating the exposed surfaces of the semiconductor layers 102 and the substrate 100. For example, the surface passivation process may include performing a plasma treatment by using H₂ plasma, so as to form Si—H terminated surfaces on the exposed surfaces of the semiconductor layers 102 and NH terminated surfaces on the exposed surfaces of the inner spacers 117. The Si—H terminated surfaces may suppress the growth rate of the protective layers 120. That is, the protective layers 120 may include higher deposition rate on the NH terminated surfaces than on the Si—H terminated surfaces. As a result, the protective layers 120 may be selectively formed on the non-passivated surfaces of the inner spacers 117 (and/or the gate spacers 115, see FIG. 7).

Reference is made to FIG. 8. Source/drain epitaxial structures 140 are formed in the source/drain openings O1. The source/drain epitaxial structures 140 may be formed by suitable deposition process, such as a selective epitaxial growth (SEG) process. In some embodiments, the SEG process may selectively grow a semiconductor material on exposed semiconductor surfaces, such as the exposed surfaces of the substrate 100 and the exposed surfaces of the semiconductor layers 102. In some embodiments, an implantation process may be performed to the source/drain epitaxial structures 140. For example, when the device is an N-type device, the source/drain epitaxial structures 140 may be doped with n-type dopants, such as phosphorus (P), arsenic (As), or antimony (Sb), or the like. Alternatively, when the device is a P-type device, the source/drain epitaxial structures 140 may be doped with p-type dopants, such as boron (B), gallium (Ga), indium (In), aluminium (Al), or the like.

In some embodiments, because the source/drain epitaxial structures 140 the exposed surfaces of the substrate 100 and the exposed surfaces of the semiconductor layers 102, during the growth of the source/drain epitaxial structures 140, the source/drain epitaxial structures 140 may extend to the protective layers 120 and may further cover the exposed surfaces of the protective layers 120. However, portions of the protective layers 120 on sidewalls of the gate spacers 115 may be free of coverage by the source/drain epitaxial structures 140. This is because the epitaxial growth of the source/drain epitaxial structures 140 may be stopped prior to the source/drain epitaxial structures 140 reach the portions of the protective layers 120 on sidewalls of the gate spacers 115.

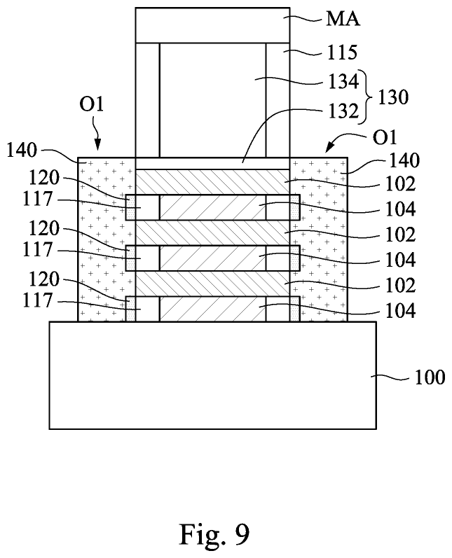

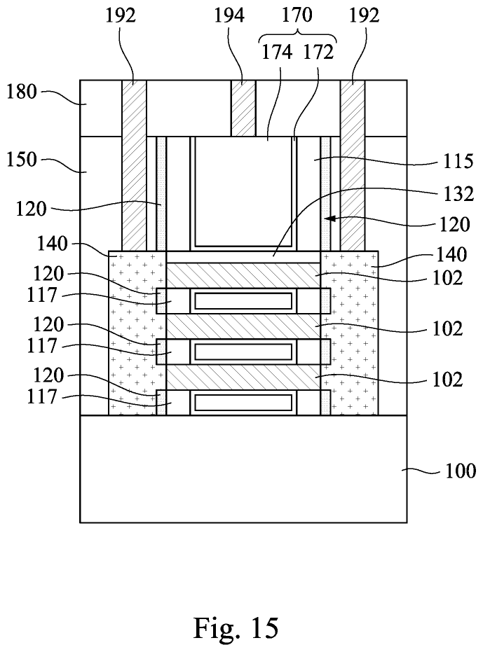

Reference is made to FIG. 9. The portions of the protective layers 120 on sidewalls of the gate spacers 115 may be removed through an etching process, so as to expose the outer sidewalls of the gate spacers 115. In other embodiments, the portions of the protective layers 120 on sidewalls of the gate spacers 115 may not be removed, and the resulting structure is shown in FIG. 15.

Reference is made to FIG. 10. An interlayer dielectric (ILD) layer 150 is formed over the substrate 100 and covering the source/drain epitaxial structures 140. Then, a planarization process, such as CMP, is performed to remove excess material of the ILD layer 150, such that top surface of the dummy gate structure 130 is exposed. During the planarization process, the hard mask HM (see FIG. 9) may be removed. In some embodiments, the ILD layer 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 150 can be formed using, for example, CVD, ALD or other suitable techniques. In some embodiments, a contact etch stop layer (not shown) may be formed over the substrate 100 prior to forming the ILD layer 150. The contact etch stop layer may be dielectric layer including silicon nitride, silicon oxynitride or other suitable materials.

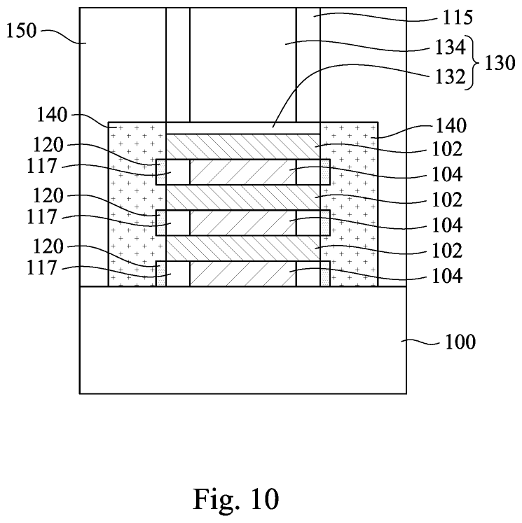

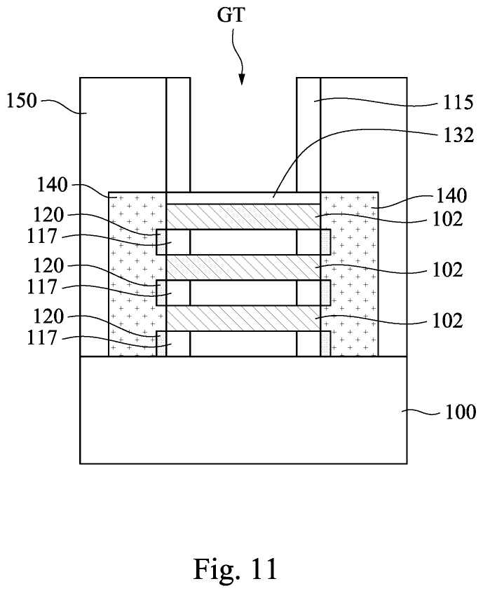

Reference is made to FIG. 11. The dummy gate structure 130 is removed to form a gate trench GT between the gate spacers 115. Then, an etching process is performed to remove the semiconductor layers 104 through the gate trench GT, such that the semiconductor layers 102 are suspended over the substrate 100. In some embodiments, the dummy gate structure 130 and the semiconductor layers 102 may be removed using suitable etching process, such as dry etch, wet etch, or the like.

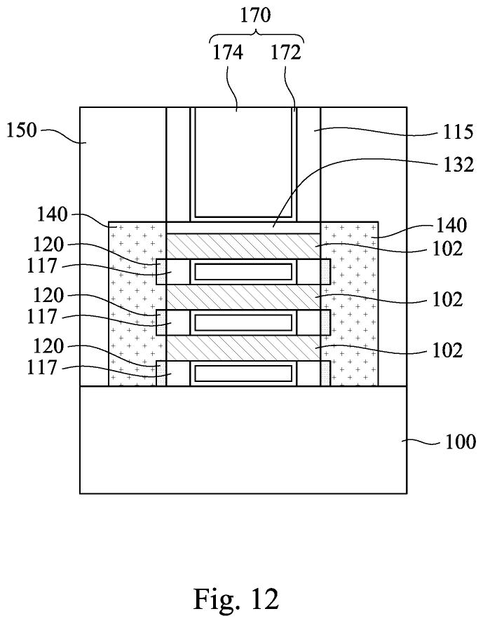

Reference is made to FIG. 12. A metal gate structure 170 is formed in the gate trenches GT and wrapping around each of the semiconductor layers 102. In some embodiments, the metal gate structure 170 includes an interfacial layer (not shown), a gate dielectric layer 172 and a gate metal 174. Then, a planarization process, such as CMP, is performed to remove excess materials of the gate dielectric layer 172 and the gate metal 174 until the ILD layer 150 is exposed.

In some embodiments, the interfacial layers may be made of oxide, such as aluminum oxide (Al₂O₃), silicon oxide (SiO₂), or the like. In some embodiments, the gate dielectric layer 172 may include high-k dielectric. Examples of high-k dielectric material include HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate metal 174 may include a function metal layer and a filling metal over the function metal layer. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

The metal gate structure 170, the source/drain epitaxial structures 140 on opposite sides of the metal gate structure 170, and the semiconductor layers 102 that are in contact with the source/drain epitaxial structures 140 may collectively serve as a transistor.

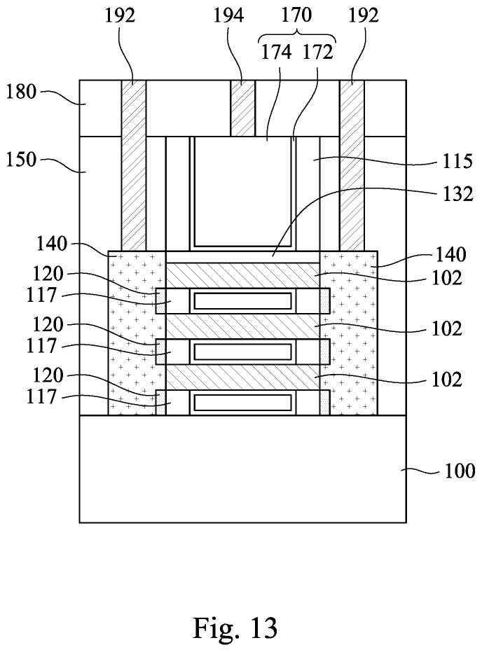

Reference is made to FIG. 13. An interlayer dielectric (ILD) layer 180 is formed over the ILD layer 150 and covering the metal gate structure 170. In some embodiments, the ILD layer 180 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 180 can be formed using, for example, CVD, ALD or other suitable techniques.

Afterwards, conductive features 192 and 194 are formed, in which the conductive features 192 are formed extending through the ILD layers 180 and 150 and in contact with the respective source/drain epitaxial structures 140, and the conductive feature 194 is formed extending through the ILD layer 180 and in contact with the metal gate structure 170. In some embodiments, the conductive features 192 and 194 may be formed by, for example, patterning the ILD layers 180 and 150 to form openings that expose the source/drain epitaxial structures 140 and the metal gate structure 170, filling the openings with conductive material, and then performing a CMP process to remove excess conductive material until the ILD layer 180 is exposed. The conductive features 192 and 194 may be made of metal, such as tungsten (W), copper (Cu), aluminum (Al), ruthenium (Ru), cobalt (Co), molybdenum (Mo), nickel (Ni), or other suitable conductive material. In some embodiments, the conductive features 192 may also be referred to as source/drain contacts, and the conductive feature 194 may also be referred to as gate via.

Embodiments of the present disclosure provide a method by selectively forming protective layers 120 on the inner spacers 117. The protective layers 120 can protect the source/drain epitaxial structures 140 during a replacement gate process. For example, as discussed in FIG. 11, during the replacement gate process, several etching processes may be performed to remove the dummy gate structure 130 and the semiconductor layers 104, the etching processes may unwantedly etch the inner spacers 117 through the gate trench GT. In some embodiments, some of the inner spacers 117 may be punched through during the replacement gate process and a gap may be formed in the inner spacer 117. If the protective layers 120 are omitted, the gap may be in communication with a corresponding source/drain epitaxial structure 140. Accordingly, once the metal gate structure 170 is formed, material of the metal gate structure 170 may be unwantedly short to the source/drain epitaxial structures 140. However, the protective layers 120 may act as an etch stop layer (or barrier layer) that has higher etch resistant to the etchants for etching the dummy gate structure 130 and the semiconductor layers 104. Accordingly, the protective layers 120 may prevent unwanted electrical connection between the metal gate structure 170 and the source/drain epitaxial structures 140.

Moreover, the protective layers 120 may be made of boron nitride (BN). BN is known having greater etch resistant against many chemistries of wet etch or dry etch. Also, BN can be selectively deposited only on inner spacer material. Due to etch resistant quality of BN material, thin layer cap can be beneficial against dummy gate and SiGe etch chemistries. Additionally, BN has low k (<3.0) value which is beneficial in keeping low parasitic capacitance or Cgd.

FIG. 15 illustrates a semiconductor device in accordance with some embodiments of the present disclosure. The structure of FIG. 15 is similar to the structure of FIG. 13, and thus similar elements are labeled the same. The structure of FIG. 15 is different from the structure of FIG. 13, in that the portions of the protective layers 120 on sidewalls of the gate spacers 115 are not removed. That is, the process discussed in FIG. 9 may be skipped, and the resulting structure is shown in FIG. 15. As a result, the portion of the protective layers 120 on the sidewall of the respective gate spacer 115 is between the gate spacer 115 and the ILD layer 150. In some embodiments, the source/drain epitaxial structures 140 may also be in contact with the portions of the protective layers 120.

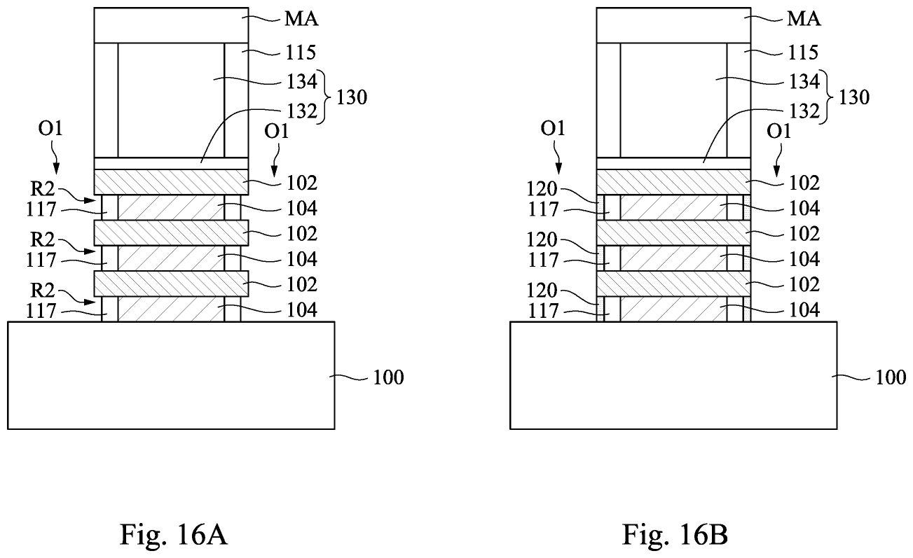

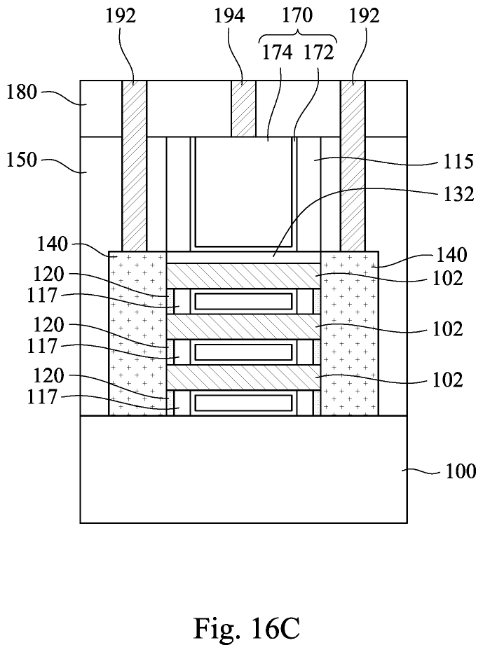

FIGS. 16A to 16C illustrate a method in various stages of forming a semiconductor device in accordance with some embodiments of the present disclosure. It is noted that some elements of FIGS. 16A to 16C are the same as those described with respect to FIGS. 1 to 13, such elements are labeled the same and relevant details will not be repeated for brevity.

In FIG. 16A, during forming the inner spacers 117, the sidewalls of the inner spacers 117 may be slightly pulled back, such that sidewall recesses R2 are formed on opposite sides of each inner spacer 117.

In FIG. 16B, the protective layers 120 are formed on opposite sidewalls of the inner spacers 117. In greater detail, the protective layers 120 may be formed in the sidewall recesses R2. Accordingly, each protective layer 120 may be in contact with bottom surface of its overlying semiconductor layer 102 and top surface of its underlying semiconductor layer 102. The protective layers 120 may be formed using the selective deposition process discussed above, and thus details are not repeated. In some embodiments, outer sidewalls of the protective layers 120 may be substantially aligned with outer sidewalls of the semiconductor layers 102, while the disclosure is not limited thereto.

In FIG. 16C, the structure of FIG. 16B may undergo the processes as discussed with respect to FIGS. 8 to 13, and the resulting structure is shown in FIG. 16C. In some embodiments, the inner spacers 117 may be spaced apart from the source/drain epitaxial structures 140 through the protective layers 120.

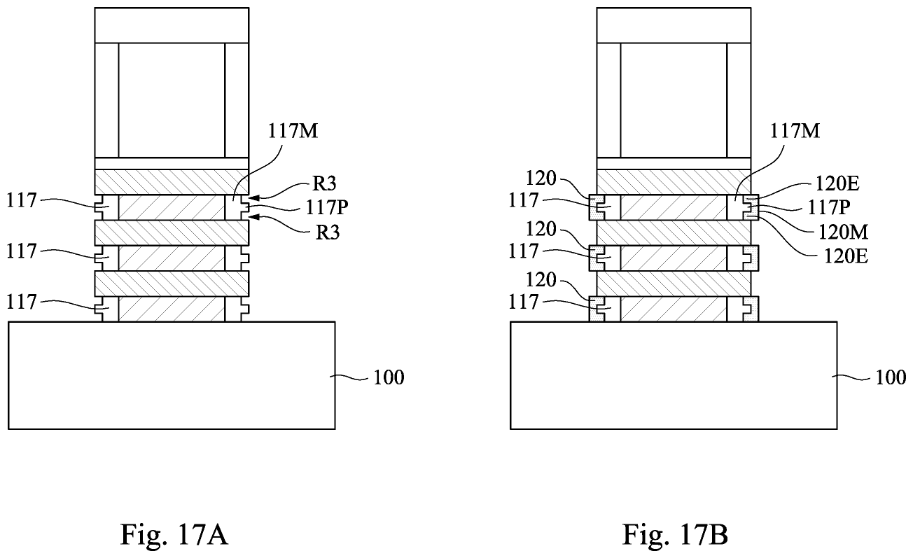

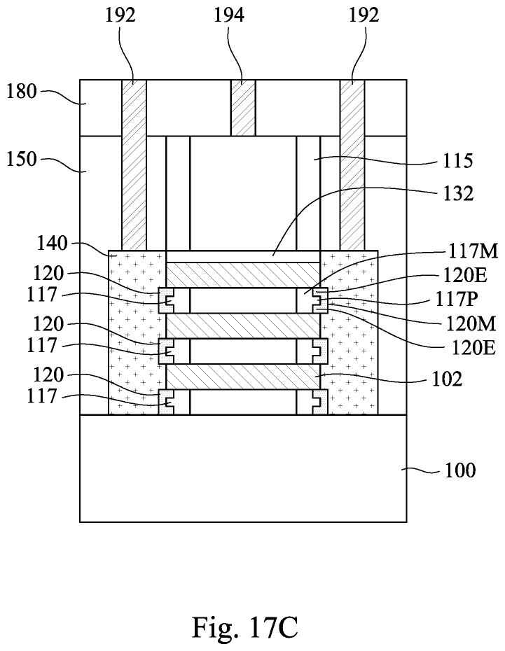

FIGS. 17A to 17C illustrate a method in various stages of forming a semiconductor device in accordance with some embodiments of the present disclosure. It is noted that some elements of FIGS. 17A to 17C are the same as those described with respect to FIGS. 1 to 13, such elements are labeled the same and relevant details will not be repeated for brevity.

In FIG. 17A, during forming the inner spacers 117, the sidewalls of the inner spacers 117 may be irregularly etched, such that sidewall recesses R3 are formed on opposite sides of each inner spacer 117. As a result, each inner spacer 117 may include a protrusion portion 117P protrudes outwards from the main portion 117M of the inner spacer 117, in which the main portion 117M may be the portion of the inner spacer 117 that extends continuously from bottom surface of its overlying semiconductor layer 102 to top surface of its underlying semiconductor layer 102, or the portion that extends continuously from bottom surface of its overlying semiconductor layer 102 to top surface of the substrate 100 (for bottommost inner spacer 117).

In FIG. 17B, the protective layers 120 are formed on opposite sidewalls of the inner spacers 117. In greater detail, the protective layers 120 may be formed in the sidewall recesses R3. In some embodiments, each protective layer 120 may include a portion 120M outside the sidewall recesses R3, and extension portions 120E formed in the sidewall recesses R3. In some embodiments, the extension portions 120E may be in contact with the protrusion portion 117P of the respective inner spacer 117. In some embodiments, the extension portions 120E may be in contact with bottom surface of the overlying semiconductor layer 102 or top surface of the underlying semiconductor layer 102.

In FIG. 17C, the structure of FIG. 17B may undergo the processes as discussed with respect to FIGS. 8 to 13, and the resulting structure is shown in FIG. 17C. In some embodiments, the source/drain epitaxial structures 140 may cover top surface, bottom surface, and outer sidewall of the portion 120M of each protective layer 120. In some embodiments, each protective layer 120 can be regarded as having a portion 120M embedded in the respective source/drain epitaxial structure 140.

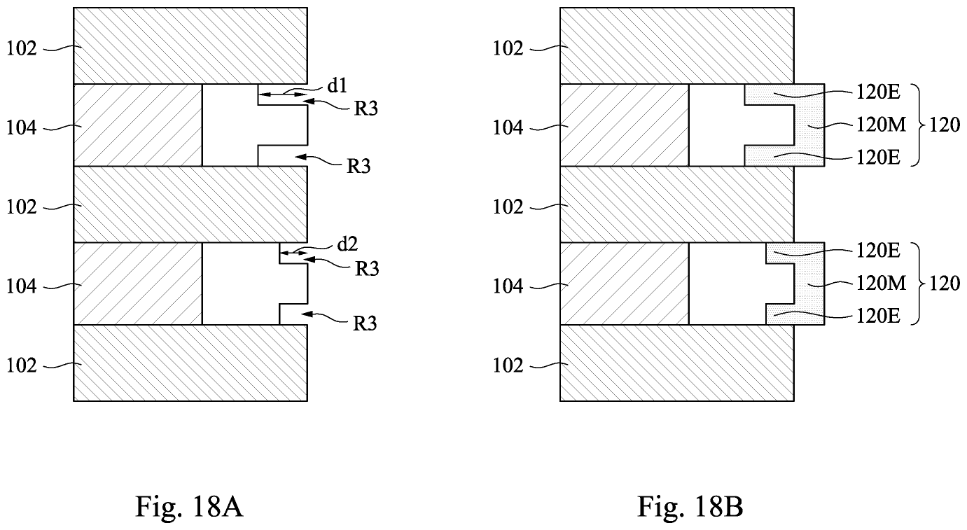

FIGS. 18A to 18B illustrate a method in various stages of forming a semiconductor device in accordance with some embodiments of the present disclosure. It is noted that some elements of FIGS. 18A to 18B are the same as those described with respect to FIGS. 17A to 17C, such elements are labeled the same and relevant details will not be repeated for brevity.

In FIG. 18A, during forming the inner spacers 117, the sidewalls of the inner spacers 117 may be irregularly etched, such that sidewall recesses R3 are formed on opposite sides of each inner spacer 117. However, the inner spacer 117 at upper level may be etched at a greater etching rate than the inner spacer 117 at lower level. This will result in that a width d1 of the sidewall recess R3 at upper level is deeper than a width d2 of the sidewall recess R3 at lower level.

In FIG. 18B, the protective layers 120 are formed on opposite sidewalls of the inner spacers 117. In greater detail, the protective layers 120 may be formed in the sidewall recesses R3. Because the width d1 of the sidewall recess R3 at upper level is deeper than the width d2 of the sidewall recess R3 at lower level, the extension portion 120E of the protective layer 120 at upper level is also wider than the extension portion 120E of the protective layer 120 at lower level.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method by forming protective layers on outer sidewalls of the respective inner spacers. During the replacement gate process, the protective layers may act as an etch stop layer (or barrier layer) that has higher etch resistant to the etchants for etching the dummy gate structure and the sacrificial semiconductor layers.

In some embodiments of the present disclosure, a semiconductor device includes a substrate. Semiconductor channel layers are over the substrate. A gate structure wraps around each of the semiconductor channel layers. Source/drain epitaxial structures are on opposite sides of the gate structure. An inner spacer is vertically between adjacent two of the semiconductor channel layers. A dielectric protective layer is on a sidewall of the inner spacer.

In some embodiments, the dielectric protective layer is in contact with one of the source/drain epitaxial structures.

In some embodiments, the inner spacer is spaced apart from the one of the source/drain epitaxial structures through the dielectric protective layer.

In some embodiments, the one of the source/drain epitaxial structures covers a top surface and a bottom surface of the dielectric protective layer.

In some embodiments, the dielectric protective layer is in contact with the adjacent two of the semiconductor channel layers.

In some embodiments, the dielectric protective layer is made of a different material than the inner spacer.

In some embodiments, a lateral width of the dielectric protective layer is less than a lateral width of the inner spacer.

In some embodiments of the present disclosure, a semiconductor device includes a substrate. Semiconductor channel layers are over the substrate. A gate structure wraps around each of the semiconductor channel layers. Source/drain epitaxial structures are on opposite sides of the gate structure. A first inner spacer is vertically between adjacent two of the semiconductor channel layers. A first protective layer is between the first inner spacer and one of the source/drain epitaxial structures and spatially separating the first inner spacer from the one of the source/drain epitaxial structures.

In some embodiments, the semiconductor device further includes a second inner spacer between a bottommost one of the semiconductor channel layers and the substrate. A second protective layer is between the second inner spacer and the one of the source/drain epitaxial structures, in which the second protective layer is in contact with the substrate.

In some embodiments, the first protective layer has a first portion in contact with the adjacent two of the semiconductor channel layers, and the second protective layer has a second portion in contact with the bottommost one of the semiconductor channel layers and the substrate, and in which the first portion is wider than the second portion.

In some embodiments, the first protective layer is made of boron nitride.

In some embodiments, the first protective layer has an extension portion extending to a region vertically between the adjacent two of the semiconductor channel layers, and a portion outside the region vertically between the adjacent two of the semiconductor channel layers.

In some embodiments, the first protective layer has a portion embedded in the one of the source/drain epitaxial structures.

In some embodiments, an outer sidewall of the first protective layer is substantially aligned with a sidewall of one of the semiconductor channel layers.

In some embodiments, the semiconductor device further includes a gate spacer on a sidewall of the gate structure. A second protective layer is on a sidewall of the gate spacer, wherein the first protective layer and the second protective layer are made of a same material.

In some embodiments of the present disclosure, a method includes forming semiconductor channel layers over a substrate; forming inner spacers between adjacent two of the semiconductor channel layers; selectively forming protective layers on outer sidewalls of the inner spacers; forming source/drain epitaxial structures on opposite sides of each of the semiconductor channel layers; and forming a gate structure wrapping around each of the semiconductor channel layers.

In some embodiments, selectively forming the protective layers on outer sidewalls of the inner spacers includes performing a surface passivation treatment to passivate exposed surfaces of the semiconductor channel layers, while leaving exposed surfaces of the inner spacers non-passivated; and performing a deposition process to depositing a material of the protective layers on the exposed surfaces of the inner spacers, while leaving the exposed surfaces of the semiconductor channel layers substantially free of coverage by the material of the protective layers.

In some embodiments, performing the surface passivation treatment further comprises forming inhibitors on the exposed surfaces of the semiconductor channel layers, and the method further includes performing an etching process to remove the inhibitors after the deposition process is complete.

In some embodiments, the inhibitors comprise —Si(CH₃)₃ groups.

In some embodiments, the protective layers are made of boron nitride, wherein the boron nitride has a higher deposition rate on the outer sidewalls of the inner spacers than on sidewalls of the semiconductor channel layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
semiconductor channel layers over the substrate;
a gate structure wrapping around each of the semiconductor channel layers;
source/drain epitaxial structures on opposite sides of the gate structure;
an inner spacer vertically between adjacent two of the semiconductor channel layers; and
a dielectric protective layer on a sidewall of the inner spacer.

2. The semiconductor device of claim 1, wherein the dielectric protective layer is in contact with one of the source/drain epitaxial structures.

3. The semiconductor device of claim 2, wherein the inner spacer is spaced apart from the one of the source/drain epitaxial structures through the dielectric protective layer.

4. The semiconductor device of claim 2, wherein the one of the source/drain epitaxial structures covers a top surface and a bottom surface of the dielectric protective layer.

5. The semiconductor device of claim 1, wherein the dielectric protective layer is in contact with the adjacent two of the semiconductor channel layers.

6. The semiconductor device of claim 1, wherein the dielectric protective layer is made of a different material than the inner spacer.

7. The semiconductor device of claim 1, wherein a lateral width of the dielectric protective layer is less than a lateral width of the inner spacer.

8. A semiconductor device, comprising:
a substrate;
semiconductor channel layers over the substrate;
a gate structure wrapping around each of the semiconductor channel layers;
source/drain epitaxial structures on opposite sides of the gate structure;
a first inner spacer vertically between adjacent two of the semiconductor channel layers; and
a first protective layer between the first inner spacer and one of the source/drain epitaxial structures and spatially separating the first inner spacer from the one of the source/drain epitaxial structures.

9. The semiconductor device of claim 8, further comprising:
a second inner spacer between a bottommost one of the semiconductor channel layers and the substrate; and
a second protective layer between the second inner spacer and the one of the source/drain epitaxial structures, wherein the second protective layer is in contact with the substrate.

10. The semiconductor device of claim 9, wherein the first protective layer has a first portion in contact with the adjacent two of the semiconductor channel layers, and the second protective layer has a second portion in contact with the bottommost one of the semiconductor channel layers and the substrate, and wherein the first portion is wider than the second portion.

11. The semiconductor device of claim 8, wherein the first protective layer is made of boron nitride.

12. The semiconductor device of claim 8, wherein the first protective layer has an extension portion extending to a region vertically between the adjacent two of the semiconductor channel layers, and a portion outside the region vertically between the adjacent two of the semiconductor channel layers.

13. The semiconductor device of claim 8, wherein the first protective layer has a portion embedded in the one of the source/drain epitaxial structures.

14. The semiconductor device of claim 8, wherein an outer sidewall of the first protective layer is substantially aligned with a sidewall of one of the semiconductor channel layers.

15. The semiconductor device of claim 8, further comprising:
a gate spacer on a sidewall of the gate structure; and
a second protective layer on a sidewall of the gate spacer, wherein the first protective layer and the second protective layer are made of a same material.

16. A method, comprising:
forming semiconductor channel layers over a substrate;
forming inner spacers between adjacent two of the semiconductor channel layers;
selectively forming protective layers on outer sidewalls of the inner spacers;
forming source/drain epitaxial structures on opposite sides of each of the semiconductor channel layers; and
forming a gate structure wrapping around each of the semiconductor channel layers.

17. The method of claim 16, wherein selectively forming the protective layers on outer sidewalls of the inner spacers comprises:
performing a surface passivation treatment to passivate exposed surfaces of the semiconductor channel layers, while leaving exposed surfaces of the inner spacers non-passivated; and
performing a deposition process to depositing a material of the protective layers on the exposed surfaces of the inner spacers, while leaving the exposed surfaces of the semiconductor channel layers substantially free of coverage by the material of the protective layers.

18. The method of claim 17, wherein performing the surface passivation treatment further comprises forming inhibitors on the exposed surfaces of the semiconductor channel layers, and the method further comprises:
performing an etching process to remove the inhibitors after the deposition process is complete.

19. The method of claim 18, wherein the inhibitors comprise —Si(CH₃)₃ groups.

20. The method of claim 16, wherein the protective layers are made of boron nitride, wherein the boron nitride has a higher deposition rate on the outer sidewalls of the inner spacers than on sidewalls of the semiconductor channel layers.
